(19) United States
(12) Patent Application Publication
(10) Pub. No.: US 2006/0220043 A1
(43) Pub. Date: Oct. 5, 2006

(54) Nitride semiconductor light emitting device

(75) Inventors: Hyun Kyung Kim, Suwon (KR); Hyoun Soo Shin, Seoul (KR); Hyuk Min Lee, Seoul (KR); In Joon Pyeon, Suwon (KR); Chang Wan Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/328,196

(22) Filed: Jan. 10, 2006

(30) Foreign Application Priority Data
Mar. 30, 2005 (KR) 10-2005-0026514

(51) Int. Cl. H01L 33/00

(52) U.S. Cl. 257/96

(57) ABSTRACT

The present invention relates to a nitride semiconductor light emitting device having a rectangular top view in which n-electrode and p-electrode structure is appropriately formed to improve propagation of currents and enhance luminance. The light emitting device includes an n-type nitride semiconductor layer formed on a substrate, and an n-electrode including an n-side bonding pad and a finger-type n-electrode extending away from the n-side bonding pad. The device further includes a mesa structure including an active layer and a p-type nitride semiconductor layer deposited in their order, an ohmic contact layer formed on a substantially entire upper surface of the mesa structure, and a p-electrode including a p-side bonding pad and a finger-type p-electrode extending away from the p-side bonding pad.

### CLAIM OF PRIORITY

This application claims the benefit of Korean Patent Application No. 2005-26514 filed on Mar. 30, 2005, in the Korean Intellectual Property Office, the disclosure of which is incorporated herein by reference.

### BACKGROUND OF THE INVENTION

1. Field of the Invention

The present invention relates to a nitride semiconductor light emitting device, and more particularly, to a nitride semiconductor light emitting device having a substantially rectangular top view, in which n- and p-electrodes are appropriately structured to improve current spreading and enhance luminance.

2. Description of the Related Art

In general, a nitride semiconductor is a III-V group semiconductor crystal such as GaN, InN, and AlN, and it is widely used particularly in a light emitting device capable of emitting blue light.

The nitride semiconductor light emitting device is fabricated using insulation substrates such as a sapphire substrate or a SiC substrate that satisfies lattice matching for crystal growth, and thus has a planar structure in which two electrodes connected to p-type and n-type nitride semiconductor layers are disposed substantially horizontally on the upper surface of the light emitting structure.

FIG. 1(a) is a plan view illustrating a conventional nitride semiconductor light emitting device. The conventional nitride semiconductor light emitting device 10 shown in FIG. 1(a) is fabricated by first forming an n-type nitride semiconductor layer 12, an active layer (not shown), a p-type nitride semiconductor layer 14, and an ohmic contact layer 15 in their order on a sapphire substrate (not shown), and etching a part of the active layer, the p-type nitride semiconductor layer 14, and the ohmic contact layer 15 to form a mesa structure, and then exposing a part of the upper surface of the n-type nitride semiconductor layer 12. In addition, the conventional nitride semiconductor light emitting device 10 has an n-electrode 17 in an exposed upper surface of the n-type nitride semiconductor layer 12, and a p-electrode 16 on the upper surface of an ohmic contact layer 15. The n-electrode 17 and the p-electrode 16 are electrically connected to exterior electrodes by wire bonding or flip-chip bonding and injected with current, and thereby, light is produced in the active layer.

As shown in FIG. 1(a), such conventional nitride semiconductor light emitting device 10 is fabricated to have a square top view (e.g. 400 μm×400 μm), having a structure appropriate for current spreading and convenient for processing.

However, for the nitride semiconductor light emitting device used in a particular package such as a Lucid Crystal Display (LCD) SideView of a mobile phone, the rectangular top view of light emitting device is required to not only reduce the width but also to retain the area of a mesa structure where light emission takes place. FIG. 1(b) is a diagram illustrating the nitride semiconductor light emitting device having a rectangular top view and having an electrode structure used in the conventional nitride semiconductor light emitting device having a square top view shown in FIG. 1(a).

As shown in FIG. 1(b), the nitride semiconductor light emitting device 20 having a rectangular top view with the same electrode structure as the nitride semiconductor light emitting device having a square top view shown in FIG. 1(a) has problems in that the distance between the p-electrode 26 and the n-electrode 27 is longer while most of the currents injected through both electrodes run through the shortest path between both electrodes. Therefore, current spreading is weakened and current distribution is concentrated in some parts, thereby decreasing the region of the active area in the mesa structure involved in light emission, which in turn deteriorates the luminance.

Therefore, a new electrode structure is required in the art to improve current spreading and luminance of the nitride semiconductor light emitting device having a rectangular top view used for the LCD SideView.

### SUMMARY OF THE INVENTION

The present invention has been made to solve the foregoing problems of the prior art and it is therefore an object of the present invention to provide a nitride semiconductor light emitting device having a substantially rectangular top view in which n- and p-electrodes are appropriately structured to improve current spreading and enhance luminance.

According to an aspect of the invention for realizing the object, there is provided a nitride semiconductor light emitting device having a rectangular top view composed of two short edges and two long edges, including: an n-type nitride semiconductor layer formed on a substrate; an n-electrode including an n-side bonding pad expanding from a corner on an upper surface of the n-type nitride semiconductor layer and a finger-type n-electrode extending away from the n-side bonding pad; a mesa structure including an active layer and a p-type nitride semiconductor layer deposited in their order on a portion of the n-type nitride semiconductor layer where the n-electrode is not formed; an ohmic contact layer formed on a substantially entire upper surface of the mesa structure; and a p-electrode including a p-side bonding pad expanding from the center of a short edge that does not compose the corner in which the n-side bonding pad is positioned and a finger-type p-electrode extending away from the p-side bonding pad.

In a preferred embodiment of the present invention, the finger-type n-electrode extends along a long edge composing the corner in which the n-side bonding pad is positioned, and the finger-type p-electrode extends along the short edge which the p-side bonding pad is positioned adjacent to and along the other long edge facing the long edge in which the finger-type n-electrode is positioned. More preferably, the end portions of the finger-type n-electrode and the finger-type p-electrode are opposed to each other in part.

In such electrode structure, it is preferable that the minimum distance between the distal end of the finger-type n-electrode and the p-side bonding pad, the minimum distance between the distal end of the finger-type p-electrode and the n-side bonding pad, and the minimum distance between the opposed parts of the finger-type n-electrode and the finger-type p-electrode are all substantially equal.

In addition, it is preferable that the n-electrode is spaced from the mesa structure at a predetermined distance.

### BRIEF DESCRIPTION OF THE DRAWINGS

The above and other objects, features and other advantages of the present invention will be more clearly understood from the following detailed description taken in conjunction with the accompanying drawings, in which:

FIGS. 1(a) and (b) are plan views illustrating an electrode structure of a conventional nitride semiconductor light emitting device; and

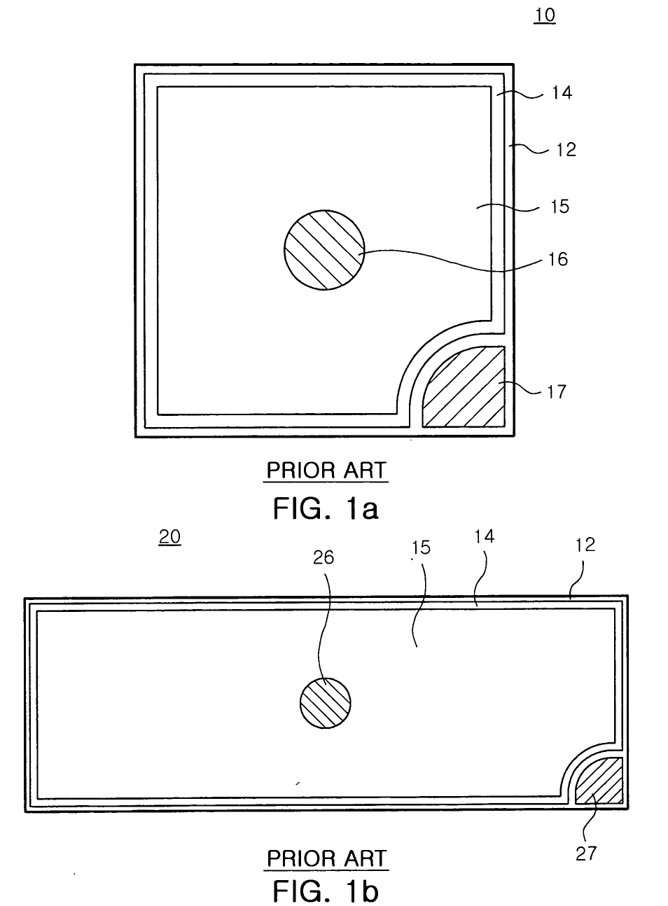

FIG. 2 (a) is a plan view illustrating an electrode structure of a nitride semiconductor light emitting device according to the present invention, and (b) is a side sectional view illustrating the nitride semiconductor light emitting device according to the present invention.

### DETAILED DESCRIPTION OF THE PREFERRED EMBODIMENT

Preferred embodiments of the present invention will now be described in detail with reference to the accompanying drawings. Same reference numerals are used throughout the different drawings to designate the same or similar components.

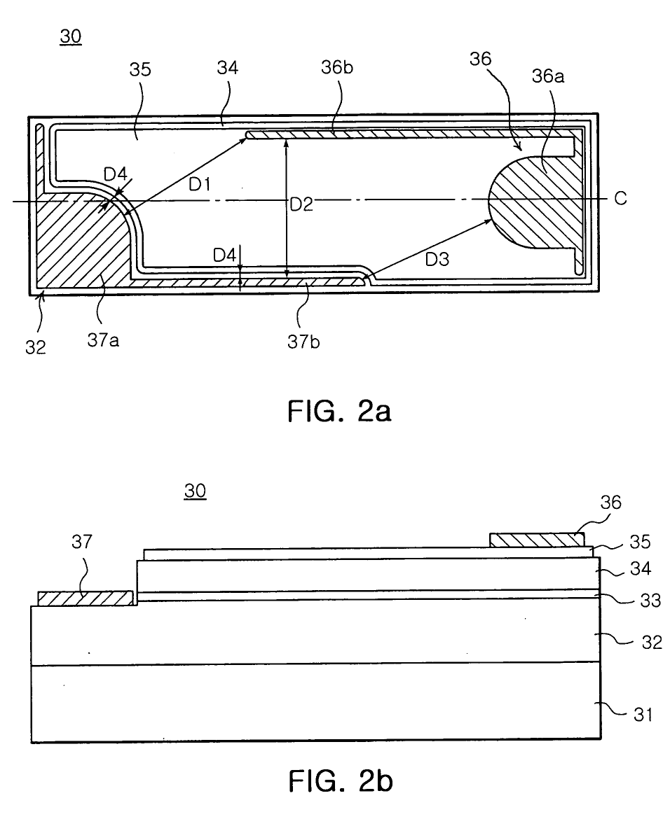

FIG. 2(a) is a plan view and FIG. 2(b) is a sectional view of a nitride semiconductor light emitting device according to an embodiment of the present invention. Referring to FIG. 2(a) and (b), the nitride semiconductor light emitting device 30 for flip chip according to an embodiment of the present invention has a rectangular top view composed of two short edges of the same length and two long edges of the same length that is longer than the short edges. At this time, the nitride semiconductor light emitting device 30 for flip chip according to an embodiment of the present invention, includes an n-type nitride semiconductor layer 32 formed on a substrate 31; an n-electrode 37 including an n-side bonding pad 37a expanding from a corner on an upper surface of the n-type nitride semiconductor layer 32 and a finger-type n-electrode 37b extending away from the n-side bonding pad 37a; a mesa structure including an active layer 33 and a p-type nitride semiconductor layer 34 deposited in their order on a portion of the n-type nitride semiconductor layer 32 where the n-electrode 37 is not formed; an ohmic contact layer 35 formed on a substantially entire upper surface of the mesa structure; and a p-electrode 36 including a p-side bonding pad 36a expanding from the center of a short edge that does not compose the corner in which the n-side bonding pad 37a is positioned and a finger-type p-electrode 36b extending away from the p-side bonding pad 36a.

Since there is no substrate commercially available having the same crystal structure as the semiconductor material grown thereon and satisfying lattice matching at the same time, a sapphire substrate is mostly used for the substrate 31 in consideration of lattice matching. The sapphire substrate is a crystal having Hexa-Rhombo R3c symmetry. It has a lattice constant of 13.001 Å along c-axis, a lattice distance of 4.765 along a-axis, and sapphire's orientation planes include C(0001)plane, A(1120)plane, and R(1102)plane. The c-plane of the sapphire substrate is good for the growth of GaN film and stable in a high temperature so that it is used as a substrate for blue or green light emitting devices.

The n-type nitride semiconductor layer 32 may be composed of n-doped semiconductor material having a composition formula of AlₓIn_{y}Ga_{(1-x-y)}N (wherein, 0≦x≦1, 0≦y≦1, 0≦x+y≦1), and the most representative semiconductor materials include GaN, AlGaN, and GaInN. The impurities used in the doping of the n-type nitride semiconductor layer 32 include Si, Ge, Se, Te or C. The n-type nitride semiconductor layer 32 is formed by growing the above semiconductor material using generally known deposition processes like Metal Organic Chemical Vapor Deposition (MOCVD), Molecular Beam Epitaxy (MBE) or Hybrid Vapor Phase Epitaxy (HVPE).

In general, a buffer layer may be formed between the substrate 31 and the n-type nitride semiconductor layer 32 to reduce the stress developed by lattice mismatching. A low-temperature nucleation-growth layer such as GaN or AlN, having a typical thickness of tens of nm may be used for the buffer layer.

The n-electrode 37 includes the n-side bonding pad 37a and the finger-type n-electrode 37b.

The n-side bonding pad 37a is a part where wires are bonded for electrical connection. The bonding pad is formed in a corner on the planar rectangular surface on the n-type nitride semiconductor layer 32. FIG. 2(a) illustrates an example in which the n-side bonding pad 37a formed adjacent to the lower left corner.

The finger-type n-electrode 37b is an electrode in a shape of strip extended away from the bonding pad 37a. The finger-type n-electrode 37b prevents the concentration of the current flow to the bonding pad 37a and makes the current distribution more uniform. The finger-type n-electrode is formed along the long edge composing the corner in which the n-side bonding pad 37a is positioned. In FIG. 2(a), the n-side bonding pad 37a is formed adjacent to the corner composed of the left short edge and the lower long edge, and the finger-type n-electrode extends along the lower long edge. The n-electrode 37 is formed adjacent to the edge of the rectangle, forming a more efficient structure for light emission.

The n-electrode 37 may be a single layer or multiple layers composed of material selected from a group including Ti, Cr, Al, Cu, and Au. The n-electrode 37 may be formed via typical growing method of metal layers such as deposition or sputtering.

On an upper surface portion of the n-type nitride semiconductor layer 32 where the n-electrode is not formed, the mesa structure having the active layer 33 and a p-type nitride semiconductor layer 34 deposited in their order is formed. It is preferable that the mesa structure is formed apart in a predetermined distance D4 from the n-electrode.

The active layer 33 is a layer for emitting light, and composed of nitride semiconductor layers having a single or multiple-quantum well structure such as GaN or InGaN. The active layer 33 may be formed using generally known deposition methods such as MOCVD, MBE, or HVPE as with the n-type nitride semiconductor layer 32.

The p-type nitride semiconductor layer 34 may be composed of p-doped semiconductor material having a composition formula of AlₓIn_{y}Ga_{(1-x-y)}N (wherein, 0≦x≦1, 0≦y≦1, 0≦x+y≦1), the same as the n-type nitride semiconductor layer 32, and the most representative nitride semiconductor materials include GaN, AlGaN, and GaInN. The impurities used in the doping of the p-type nitride semiconductor layer 34 include Mg, Zn or Be. The p-type nitride semiconductor layer 34 is formed by being grown on the active layer 33, using generally known deposition methods such as MOCVD, MBE or HVPE.

The ohmic contact layer 35 needs to be formed of material appropriate for decreasing contact resistance with the p-type nitride semiconductor layer 34 having relatively high energy band gap so that current spreading is improved. At the same time, it needs to be formed of material appropriate for transmitting the light produced in the active layer 33 with minimal loss. The most representative materials appropriate for improving contact resistance and satisfying conditions for light transmission includes Ni/Au or Indium Tin Oxide (ITO), a type of conductive transparent oxide. The ohmic contact layer 35 may be formed by generally known deposition methods like Chemical Vapor Deposition (CVD) and E-beam evaporator or sputtering, and may be thermally treated in a temperature of about 400 to 900° C. in order to enhance its characteristics.

The p-electrode is formed on the high-reflectivity ohmic contact layer 35. Similar to the n-electrode described above, the p-electrode 36 includes the p-side bonding pad 36a and the finger-type p-electrode 36b.

The p-side bonding pad 36a is an area for bonding wires, and formed adjacent to the near center of the short edge that does not compose the corner in which the n-side bonding pad 37a is positioned. In FIG. 2(a), the n-side bonding pad 37a is illustrated as adjacent to the corner composed of the left short edge, and thus the p-side bonding pad 36a is illustrated as formed adjacent to the center of the right short edge.

The finger-type p-electrode 36b is formed along the short edge which the p-side bonding pad 36a is formed adjacent to and a long edge opposed to the long edge along which the finger-type n-electrode is formed. As with the finger-type n-electrode 37b, the finger-type p-electrode functions to make the current spreading uniform. In FIG. 2(a), the finger-type n-electrode 37b is illustrated as formed along the lower long edge, and thus the finger-type p-electrode 36b is formed along the right short edge and the upper long edge.

In the above described n- and p-electrode structure according to an embodiment of the present invention, it is preferable that end portions of the finger-type n-electrode 37b and the finger-type p-electrode 36b overlap each other when seen in the short edge direction. In the overlapped portions, the currents run between the two finger-type electrodes, accommodating uniform current spreading and distribution.

The most preferable for uniform current spreading and distribution is to form the minimum distance D3 between the distal end of the finger-type n-electrode 37b and the p-side bonding pad 36a, the minimum distance D1 between the distal end of the finger-type p-electrode 36b and the n-side bonding pad 37a, and the minimum distance D2 between the opposed portions of the finger-type n-electrode 37b and the finger-type p-electrode 36b substantially equal to each other. The currents tend to run through the shortest path or the minimum distance. Therefore, in the center part of the nitride semiconductor light emitting device having a planar rectangular upper surface as shown in FIG. 2(a), most of the current flow occurs between the overlapped portions of the two finger-type electrodes in the center portion. And in the left part, most of the current flow occurs through the shorter portion of finger-type p-electrode and the n-side bonding pad 37a, and in the right part, most of the current flow occurs through the finger-type n-electrode 37b and the p-side bonding pad 36a. Therefore, the current is distributed in substantially entire upper surface of the nitride semiconductor light emitting device having a rectangular top view, thereby the area of the active area involved in light emission is increased, improving luminance of the light emitting device.

As set forth above, the present invention provides shape and arrangement of the n-electrode and the p-electrode that is appropriate to improve the current spreading and distribution of the nitride semiconductor light emitting device having a rectangular top view, thereby improving luminance of the nitride semiconductor light emitting device having a rectangular top view.

While the present invention has been shown and described in connection with the preferred embodiments, it will be apparent to those skilled in the art that modifications and variations can be made without departing from the spirit and scope of the invention as defined by the appended claims.

What is claimed is:

1. A nitride semiconductor light emitting device having a rectangular top view composed of two short edges and two long edges, comprising:
an n-type nitride semiconductor layer formed on a substrate;
an n-electrode including an n-side bonding pad expanding from a corner on an upper surface of the n-type nitride semiconductor layer and a finger-type n-electrode extending away from the n-side bonding pad;
a mesa structure including an active layer and a p-type nitride semiconductor layer deposited in their order on a portion of the n-type nitride semiconductor layer where the n-electrode is not formed;
an ohmic contact layer formed on a substantially entire upper surface of the mesa structure; and
a p-electrode including a p-side bonding pad expanding from the center of a short edge that does not compose the corner in which the n-side bonding pad is positioned and a finger-type p-electrode extending away from the p-side bonding pad.

2. The nitride semiconductor light emitting device according to claim 1, wherein the finger-type n-electrode extends along a long edge composing the corner in which the n-side bonding pad is positioned, and the finger-type p-electrode extends along the short edge which the p-side bonding pad is positioned adjacent to and along the other long edge facing the long edge in which the finger-type n-electrode is positioned.

3. The nitride semiconductor light emitting device according to claim 2, wherein the end portions of the finger-type n-electrode and the finger-type p-electrode are opposed to each other in part.

4. The nitride semiconductor light emitting device according to claim 3, wherein the minimum distance between the distal end of the finger-type n-electrode and the p-side bonding pad, the minimum distance between the distal end of the finger-type p-electrode and the n-side bonding pad, and the minimum distance between the opposed parts of the finger-type n-electrode and the finger-type p-electrode are all substantially equal.

5. The nitride semiconductor light emitting device according to claim 1, wherein the n-electrode is-spaced from the mesa structure at a predetermined distance.
